(19) United States
(12) Patent Application Publication
(10) Pub. No.: US 2012/0051017 A1
(43) Pub. Date: Mar. 1, 2012

(54) Electronic Component and Method of Manufacturing the Same

(75) Inventors: Gyeong-Im Lee, Yongin-City (KR); Sung-Gon Seo, Yongin-City (KR); Jae-Mo Chung, Yongin-City (KR)

(73) Assignee: SAMSUNG MOBILE DISPLAY CO., LTD., Yongin-City (KR)

(21) Appl. No.: 13/019,370

(22) Filed: Feb. 2, 2011

(30) Foreign Application Priority Data
Aug. 30, 2010 (KR) 10-2010-0084177

(51) Int. Cl. H05K 1/18; H05K 3/34; H05K 3/30

(52) U.S. Cl. 361/761; 29/832; 29/840

(57) ABSTRACT

In electronic component which can be readily miniaturized and compacted, and which has a simple manufacturing process, and in a method of manufacturing the same, the electronic component includes a printed circuit board (PCB) having a first surface and a second surface facing each other, and a predetermined through-hole, a semiconductor device mounted in the through-hole and combined with the first surface of the PCB, and at least one passive device combined with the first surface of the PCB.

### CLAIM OF PRIORITY

This application makes reference to, incorporates the same herein, and claims all benefits accruing under 35 U.S.C. §119 from an application earlier filed in the Korean Intellectual Property Office on Aug. 30, 2010 and there duly assigned Serial No. 10-2010-0084177.

### BACKGROUND OF THE INVENTION

1. Field of the Invention

The present invention relates to an electronic component and a method of manufacturing the same, and more particularly, to an electronic component which can be easily miniaturized and compacted, and can be easily manufactured in a simple process, and a method of manufacturing the same.

2. Description of the Related Art

Recently, due to the miniaturization and light weight of electronic components, techniques for mounting semiconductor devices such as light-emitting diode packages or image sensors, and passive devices such as capacitors or connectors, on a printed circuit board (PCB) have been developed.

When electronic components, for example, key pads of mobile phones, are manufactured, passive devices such as capacitors or connectors are generally mounted on a rear surface of a PCB. However, when key buttons are pressed, light must be emitted to a front surface of a mobile phone. Therefore, a light-emitting diode is generally mounted on a front surface of the PCB.

In a conventional method of manufacturing electronic components, two SMT processes are performed with respect to the upper and lower surfaces of a PCB. Thus, a mask for the upper surface and a mask for the lower surface of the PCB are separately required, and this results in increased costs for manufacturing the masks. In addition, since two SMT processes must be performed on the upper and lower surfaces of the PCB, a process of turning over the upper and lower surfaces of the PCB is required. Therefore, the manufacturing process is complicated and takes a long time.

### SUMMARY OF THE INVENTION

To address the above and/or other problems, the present invention provides an electronic component which can be readily miniaturized and compacted, and which can be manufactured in a simple process, and a method of manufacturing the same.

The present invention also provides an electronic component, comprising: a printed circuit board (PCB) having a first surface and a second surface facing each other and a predetermined through-hole; a semiconductor device mounted in the through-hole and combined with the first surface of the PCB; and at least one passive device combined with the first surface of the PCB. The semiconductor device and the passive device(s) may be combined only with the first surface of the PCB.

The semiconductor device and the passive device(s) may not be combined with the second surface of the PCB.

The semiconductor device may be a light-emitting diode package.

The light-emitting diode package may include a protrusion unit disposed at least on an outer circumference thereof, and the protrusion unit is combined with the first surface of the PCB.

At least an adhesive member may be formed on a surface of the protrusion unit facing the first surface of the PCB, or on the first surface of the PCB, so as to combine the light-emitting diode package with the first surface of the PCB.

The adhesive member may include a solder.

The light-emitting diode package may include a package main body and a light-emitting diode chip mounted on the package main body, and the package main body may include a lead frame and a molding unit which fixes the lead frame.

A surface of the molding unit which surrounds the light-emitting diode chip may be formed so as to have a predetermined angle with respect to the light-emitting diode chip so as to form a reflection surface of light emitted from the light-emitting diode chip.

The semiconductor device and the passive device(s) may be combined with the PCB using a surface mount technology (SMT).

According to an aspect of the present invention, a method of manufacturing an electronic component comprises the steps of: preparing a PCB having a first surface and a second surface facing each other and a predetermined through-hole; mounting the semiconductor device in the through-hole and combining the semiconductor device with the first surface of the PCB 110; and combining at least one passive device with the first surface of the PCB.

The semiconductor device may be a light-emitting diode package.

The light-emitting diode package may include a protrusion unit disposed at least on a portion of an outer circumference thereof, and the step of combining the semiconductor device with the first surface of the PCB may include forming an adhesive member at least on a surface of the protrusion unit facing the first surface of the PCB or on the first surface of the PCB, and soldering the PCB and the light-emitting diode package using the adhesive member.

The semiconductor device and the passive device(s) may be combined only with the first surface of the PCB.

The combining of the semiconductor device with the first surface of the PCB and the combining of the passive device(s) with the first surface of the PCB may be performed at the same time.

According to the present invention, an electronic component can be readily miniaturized and compacted, and a process for manufacturing the electronic component is simple.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a schematic cross-sectional view of an electronic component;

FIG. 2 is a schematic cross-sectional view of an electronic component according to an embodiment of the present invention;

FIG. 3 is a magnified view of portion A of FIG. 2;

FIG. 4 is a cross-sectional view of a light-emitting diode package of the electronic component of FIG. 2;

FIG. 5 is a schematic cross-sectional view of a modified version of the electronic component of FIG. 2; and

FIGS. 6 thru 9 are cross-sectional views illustrating a method of manufacturing the electronic component according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to one skilled in the art.

Like reference numerals are used in the drawings to indicate substantially identical structures or components/parts. Since the drawings are schematically drawn, the relative dimensions and ratios in the drawings are exaggerated or reduced for clarity and convenience.

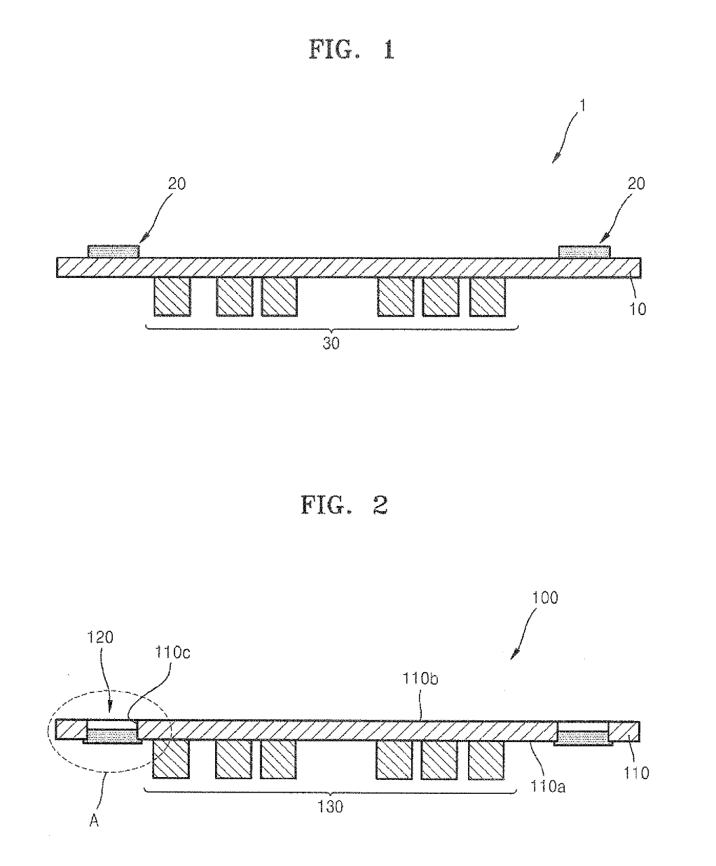

FIG. 1 is a schematic cross-sectional view of an electronic component.

Referring to FIG. 1, the electronic component 1 includes a printed circuit board (PCB) 10, a light-emitting diode package 20, and passive devices 30.

The light-emitting diode package 20 is disposed on an upper surface of the PCB 10. In this way, in order for the light-emitting diode package 20 to be disposed on the upper surface of the PCB 10, after precisely matching the light-emitting diode package 20 on a region of the upper surface of the PCB 10 where the light-emitting diode package 20 must be combined, a surface mount technology (SMT) process is performed by aligning a molded mask with respect to the PCB 10.

Also, the passive devices 30, such as capacitors or connectors, are disposed on a lower surface of the PCB 10. In this case, the PCB 10 is turned over so that the lower surface of the PCB 10 faces upward, and an SMT process is subsequently performed by aligning a mold mask with respect to the PCB 10.

In this way, two SMT processes are performed with respect to the upper and lower surfaces of the PCB 10. Thus, a mask for the upper surface and a mask for the lower surface of the PCB 10 are separately required, and accordingly, costs for manufacturing the masks are increased. In addition, since two SMT processes must be performed on the upper and lower surfaces of the PCB 10, a process of turning over the upper and lower surfaces of the PCB 10 is required. Therefore, the manufacturing process is complicated and takes a long time.

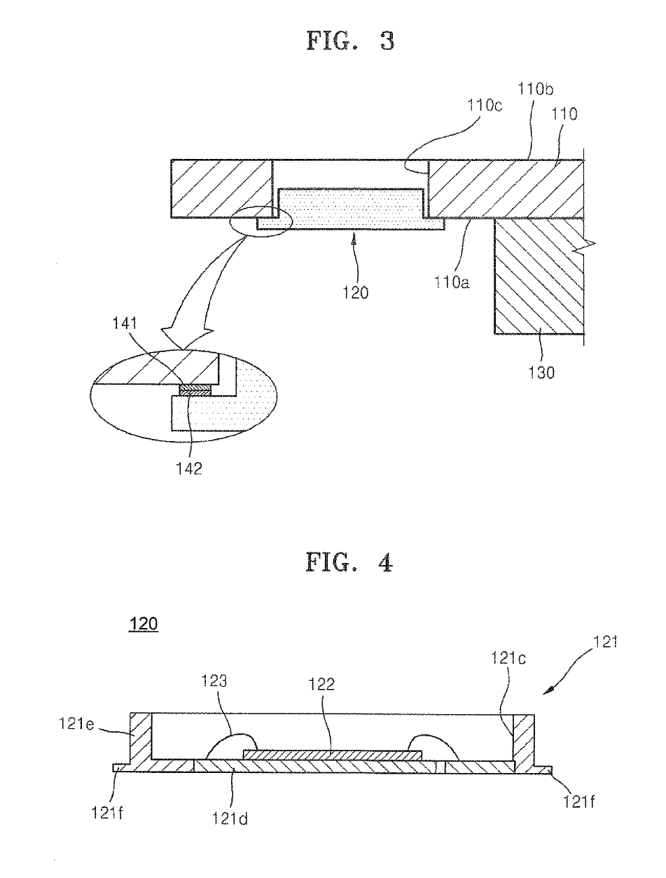

FIG. 2 is a schematic cross-sectional view of an electronic component according to an embodiment of the present invention, FIG. 3 is a magnified view of portion A of FIG. 2, and FIG. 4 is a cross-sectional view of a light-emitting diode package of the electronic component of FIG. 2.

Referring to FIGS. 2 thru 4, the electronic component 100 includes a printed circuit board (PCB) 110, a light-emitting diode package 120, and a plurality of passive devices 130.

The PCB 110 constitutes a base unit of the electronic component 100, and semiconductor devices, such as diode packages or image sensors, or the passive devices 130, such as capacitors or connectors, are disposed thereon. The PCB 110 may be a rigid flexible-printed circuit board (RF-PCB). In this regard, it is an aspect of the present invention that a through-hole 110c is formed in at least a portion, and more particularly, in a region of the PCB 110 where the light-emitting diode package 120 is formed, and this will be described in detail below.

The PCB 110 includes a first surface 110a and a second surface 110b. The first surface 110a and the second surface 110b are opposite surfaces of the PCB 110. The first surface 110a is a surface on which the light-emitting diode package 120 and the passive devices 130 are disposed, and the second surface 110b is an opposite side relative to the first surface 110a. In this regard, an aspect of the present invention is that the light-emitting diode package 120 and the passive devices 130 are disposed only on the first surface 110a of the PCB 110, and no components are mounted on the second surface 110b of the PCB 110 according to an embodiment of the present invention. This will be described in detail below.

Referring to FIG. 4, which shows the light-emitting diode package 120 of the electronic component 100, the light-emitting diode package 120 according to an embodiment of the present invention includes a package main body 121 and a light-emitting diode chip 122 which is seated on the package main body 121.

The package main body 121 includes a lead frame 121d and a molding unit 121e.

The lead frame 121d is formed of a metal having electrical conductivity, and includes an anode lead and a cathode lead separated from each other. The light-emitting diode chip 122 is disposed on a surface of the lead frame 121d. The light-emitting diode chip 122 is electrically connected to the lead frame 121d by a wire 123.

The molding unit 121e fixes the lead frame 121d. The molding unit 121e may be formed of a light resin material and forms a reflection surface 121c. In FIG. 4, the reflection surface 121c is formed by the molding unit 121e. However, the present invention is not limited thereto. That is, the reflection surface 121c may be formed by bending the lead frame 121d.

The molding unit 121e may further include a protrusion unit 121f. Also, a second adhesive member 142 (refer to FIG. 3) may be disposed on the protrusion unit 121f so as to be combined with a first adhesive member 141 (refer to FIG. 3) disposed on the PCB 110 (refer to FIG. 2). In FIG. 4, the protrusion unit 121f protrudes from the molding unit 121e. However, the present invention is not limited thereto. That is, the protrusion unit 121f may protrude from the lead frame 121d.

The light-emitting diode package 120 and the passive devices 130 are mounted on a surface of the PCB 110 (see FIG. 2). The surface mount technology (SMT) is a method of mounting surface mounted components (SMC) which can be directly mounted on the surface of a PCB.

In the latter regard, in the electronic component 100 according to an embodiment of the present invention, it is an aspect that the light-emitting diode package 120 and the passive devices 130 are mounted only on a surface of the PCB 110.

As described above with reference to FIG. 1, in a method of mounting the electronic component 1, the light-emitting diode package 20 is disposed on an upper surface of the PCB 10, and the passive devices 30, such as capacitors or connectors, are disposed on a lower surface of the PCB 10. In this case, in the SMT processes, since a mask for the upper surface of the PCB 10 and a mask for the lower surface of the PCB 10 are needed, the cost of manufacturing masks increases. Moreover, since a total of two SMT processes (that is, on the upper and lower surfaces of the PCB 110) must be performed, the manufacturing process is complicated and takes a long time.

In order to address the above problems, an aspect of the present invention is that the electronic component 100 of FIG. 2 includes the PCB 110 having first surface 110a, second surface 110b, and the predetermined through-hole 110c, and the light-emitting diode package 120 is mounted on a region where the through-hole 110c is formed. In this case, the first surface 110a of the PCB 110 and the light-emitting diode package 120 are combined with each other, and at the same time, the passive devices 130 are disposed on the first surface 110a of the PCB 110. That is, the combining of the components is performed only on the first surface 110a of the PCB 110.

In order to combine the PCB 110 and the light-emitting diode package 120, the first adhesive member 141 and the second adhesive member 142 of FIG. 3 are disposed on the PCB 110 and the light-emitting diode package 120, respectively. The first adhesive member 141 and the second adhesive member 142 include solders, and the PCB 110 and the light-emitting diode package 120 may be combined with each other by soldering them.

In this regard, soldering denotes a process of welding using a solder to constitute a circuit after a part is mounted on the PCB 110. Methods of soldering may be largely divided into two types, flow soldering and reflow soldering. Flow soldering includes a manual soldering method in which a PCB is soaked in a molten solder, and the PCB is subsequently taken out from the molten solder, and an automatic soldering method in which soldering is performed by allowing molten solder to flow onto a PCB which is conveyed by a conveyor. Also, reflow soldering denotes a method of soldering by applying heat to a PCB in an oven after applying a cream solder to the PCB. That is, a soldering process is completed in that, after applying a cream solder to a portion of a PCB to be combined, a component is placed on the PCB, and then the PCB is allowed to pass through a reflow soldering machine.

In this way, after forming the through-hole 110c in the PCB 110, the light-emitting diode package 120 is mounted in the through-hole 110c. Also, the light-emitting diode package 120 and the passive devices 130 are disposed only on the first surface 110a of the PCB 110, and are not disposed on the second surface 110b of the PCB 110. Accordingly, the miniaturization and compactness of the electronic component 100 can be easily achieved, and the manufacturing process can be simplified.

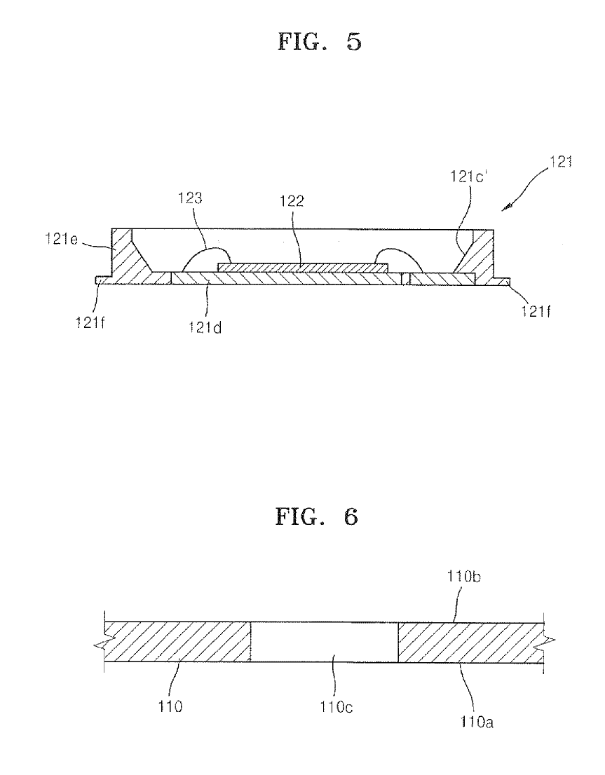

FIG. 5 is a schematic cross-sectional view of a modified version of the electronic component of FIG. 2.

Referring to FIG. 2 and FIG. 5, the electronic component 100 includes a PCB 110, a light-emitting diode package 120, and passive devices 130. The electronic component 100 according to the modified version of the present invention is distinguished from the above embodiment in that a reflection surface 121c′ (see FIG. 5) is extended so as to have a predetermined degree angle, which will now be described in detail.

In the case wherein the light-emitting diode package 120 is mounted in the through-hole 110c of the PCB 110 as shown in FIG. 2, the optical extraction efficiency of the light-emitting diode package 120 may be reduced since an optical extraction angle of light emitted from the light-emitting diode package 120 is narrowed. In order to address this problem, in the electronic component 100 according to the modified version of the present invention, the reflection surface 121c′ (FIG. 5) is formed so as to have a predetermined angle with respect to the PCB 110 (FIG. 2). Thus, the optical extraction angle of light emitted from the light-emitting diode package 120 is increased. In this way, a reduction of optical extraction efficiency of the light-emitting diode package 120 can be prevented.

A method of manufacturing the electronic component 100, according to an embodiment of the present invention, will now be described.

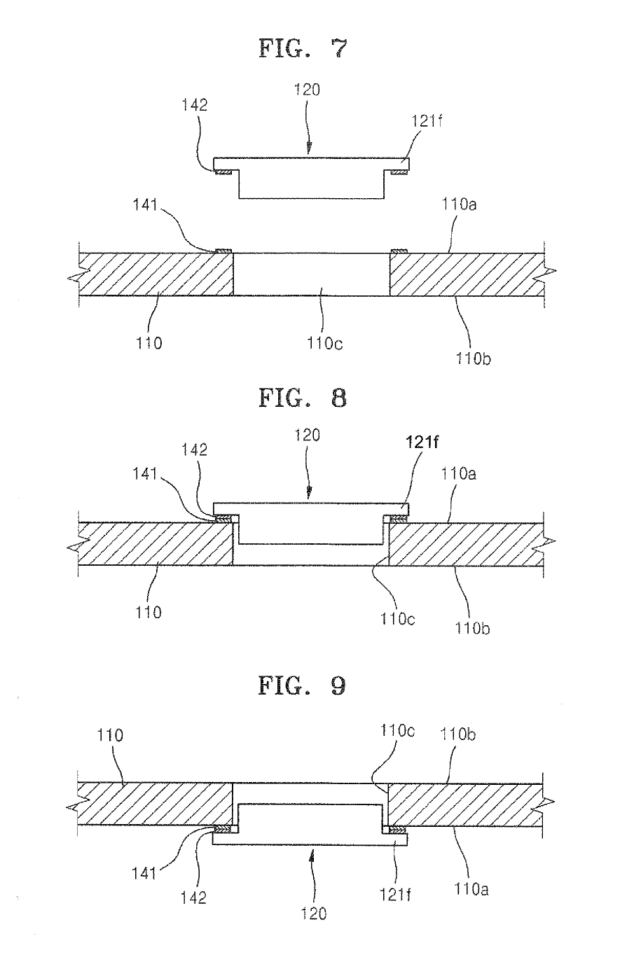

FIGS. 6 thru 9 are cross-sectional views illustrating a method of manufacturing the electronic component according to an embodiment of the present invention.

Referring to FIGS. 6 thru 9, in the method of manufacturing the electronic component 100, the method includes: forming the through-hole 110c in the PCB 110 (FIG. 6); preparing the light-emitting diode package 120 having the protrusion unit 121f on an outer circumference thereof (FIG. 7); forming an adhesive member 141, 142 at least on the first surface 110a of the PCB 110 and the protrusion unit 121f of the light-emitting diode package 120 (FIGS. 7 and 8); combining the PCB 110 and the light-emitting diode package 120 with each other (FIG. 8); and forming the passive devices 130 on the first surface 110a of the PCB 110 (FIG. 2).

FIG. 6 shows the operation of forming the through-hole 110c in the PCB 110. As shown in FIG. 6, the through-hole 110c, in which the light-emitting diode package 120 (refer to FIG. 2) is mounted, is formed in the PCB 110. The through-hole 110c may be formed using a conventional press process.

FIG. 7 shows the operation of preparing the light-emitting diode package 120 having the protrusion unit 121f on an outer circumference thereof, and forming adhesive members 141 and 142 at least on the first surface 110a of the PCB 110 and on the protrusion unit 121f of the light-emitting diode package 120, respectively.

As shown in FIG. 7, the protrusion unit 121f is formed on an outer circumference of the light-emitting diode package 120. The second adhesive member 142 may be formed on the protrusion unit 121f. In addition, the first adhesive member 141 may be formed on a location of the PCB 110 corresponding to the protrusion unit 121f. At this point, in order to facilitate the combining of the PCB 110 and the light-emitting diode package 120, the PCB 110 may be turned over so that the first surface 110a faces upward and the second surface 110b faces downward, as shown in FIG. 7.

In FIG. 7, it is depicted that the first adhesive member 141 is formed on the first surface 110a of the PCB 110 and the second adhesive member 142 is formed on the protrusion unit 121f of the light-emitting diode package 120. However, the present invention is not limited thereto. That is, the adhesive members may not necessarily be included on both the PCB 110 and the light-emitting diode package 120, but may be included only on one of the PCB 110 and the light-emitting diode package 120.

FIG. 8 shows the operation of combining the PCB 110 and the light-emitting diode package 120. As described above, the first adhesive member 141 and the second adhesive member 142 respectively include solders, and thus the PCB 110 and the light-emitting diode package 120 may be combined with each other by soldering them. At this point, most of the light-emitting diode package 120 is mounted in the through-hole 110c, and thus, miniaturization and compactness of products can be achieved.

Next, although not shown in FIG. 9, the method may further include forming the passive devices 130 on the first surface 110a of the PCB 110. That is, as shown in FIG. 8, in a combined state of the PCB 110 and the light-emitting diode package 120, the passive devices 130 may be disposed on the first surface 110a of the PCB 110 without the need to turn over the PCB 110 in order to change the positions of the first surface 110a and the second surface 110b of the PCB 110. In this way, by allowing the light-emitting diode package 120 and the passive devices 130 to be mounted on the same surface of the PCB 110, the process of manufacturing the electronic component 100 can be simplified.

In the drawings, it is depicted that the combination of the light-emitting diode package 120 with the PCB 110, and the combination of the passive devices 130 with the PCB 110, are sequentially performed. However, the present invention is not limited thereto, that is, the light-emitting diode package 120 and the passive devices 130 may be combined with the PCB 110 through a single soldering operation in a state wherein the light-emitting diode package 120 and the passive devices 130 are disposed together on the PCB 110.

Finally, when the first surface 110a and the second surface 110b of the PCB 110 are turned over, the manufacture of the electronic component 100, as shown in FIG. 9, is completed.

According to the present invention, miniaturization and compactness of an electronic component can be achieved, and the method of manufacturing the electronic component is simplified.

While the present invention has been particularly shown and described with reference to exemplary embodiments thereof, it will be understood by one of ordinary skill in the art that various changes in form and detail may be made therein without departing from the spirit and scope of the present invention as defined by the following claims.

What is claimed is:

1. An electronic component, comprising:
a printed circuit board (PCB) having a first surface and a second surface facing each other, and a predetermined through-hole;
a semiconductor device mounted in the through-hole and combined with the first surface of the PCB; and
at least one passive device combined with the first surface of the PCB.

2. The electronic component of claim 1, wherein the semiconductor device and the passive devices are combined only with the first surface of the PCB.

3. The electronic component of claim 1, wherein the semiconductor device and the passive devices are not combined with the second surface of the PCB.

4. The electronic component of claim 1, wherein the semiconductor device comprises a light-emitting diode package.

5. The electronic component of claim 4, wherein the light-emitting diode package comprises a protrusion unit on at least an outer circumference of the light-emitting diode package, and wherein the protrusion unit is combined with the first surface of the PCB.

6. The electronic component of claim 5, wherein at least an adhesive member is formed on one of a surface of the protrusion unit facing the first surface of the PCB and the first surface of the PCB so as to combine the light-emitting diode package with the first surface of the PCB.

7. The electronic component of claim 6, wherein the adhesive member comprises a solder.

8. The electronic component of claim 4, wherein the light-emitting diode package comprises a package main body and a light-emitting diode chip mounted on the package main body, and wherein the package main body comprises a lead frame and a molding unit which fixes the lead frame.

9. The electronic component of claim 8, wherein a surface of the molding unit which surrounds the light-emitting diode chip is formed so as to have a predetermined angle with respect to the light-emitting diode chip so as to form a reflection surface for light emitted from the light-emitting diode chip.

10. The electronic component of claim 1, wherein the semiconductor device and the passive devices are combined with the PCB using surface mount technology (SMT).

11. A method of manufacturing an electronic component, the method comprising the steps of:
preparing a printed circuit board (PCB) having a first surface and a second surface facing each other, and a predetermined through-hole;
mounting the semiconductor device in the through-hole and combining the semiconductor device with the first surface of the PCB; and
combining passive devices with the first surface of the PCB.

12. The method of claim 11, wherein the semiconductor device comprises a light-emitting diode package.

13. The method of claim 12, wherein the light-emitting diode package comprises a protrusion unit on at least a portion of an outer circumference of the light-emitting diode package.

14. The method of claim 13, wherein the step of combining the semiconductor device with the first surface of the PCB comprises:
forming an adhesive member on one of a surface of the protrusion unit facing the first surface of the PCB and the first surface of the PCB; and
soldering the PCB and the light-emitting diode package using the adhesive member.

15. The method of claim 12, wherein the light-emitting diode package comprises a package main body and a light-emitting diode chip mounted on the package main body, and wherein the package main body comprises a lead frame and a molding unit which fixes the lead frame.

16. The method of claim 15, wherein a surface of the molding unit which surrounds the light-emitting diode chip is formed so as to have a predetermined angle with respect to the light-emitting diode chip so as to form a reflection surface for light emitted from the light-emitting diode chip.

17. The method of claim 11, wherein the semiconductor device and the passive devices are combined only with the first surface of the PCB.

18. The method of claim 11, wherein the step of combining the semiconductor device with the first surface of the PCB and the step of combining the passive devices with the first surface of the PCB are performed at the same time.

19. The method of claim 11, wherein the semiconductor device and the passive devices are not combined with the second surface of the PCB.

20. The method of claim 11, wherein the semiconductor device and the passive devices are combined with the PCB using surface mount technology (SMT).
